(19) United States
(12) Patent Application Publication
(10) Pub. No.: US 2025/0258207 A1
(43) Pub. Date: Aug. 14, 2025

(54) MEASUREMENT STRUCTURE AND METHOD FOR MEASURING A CURRENT

(71) Applicant: Schaeffler Technologies AG & Co. KG, Herzogenaurach (DE)

(72) Inventors: Göran Schubert, Schwabach (DE); Diego Antongirolami, Nürnberg (DE); Sahaya Kulandai Raj Joseph, Zirndorf (DE)

(73) Assignee: Schaeffler Technologies AG & Co. KG, Herzogenaurach (DE)

(21) Appl. No.: 19/169,413

(22) Filed: Apr. 3, 2025

Related U.S. Application Data
(63) Continuation of application No. PCT/EP2023/075216, filed on Sep. 14, 2023.

(30) Foreign Application Priority Data
Oct. 5, 2022 (DE) 10 2022 210 524.9

(51) Int. Cl. G01R 19/25

(52) U.S. Cl. CPC G01R 19/25

(57) ABSTRACT

A measurement structure and a method for measuring a current from a center tap between two transistors of a half bridge through a load is provided. The measurement structure, for each of the two transistors, measures a voltage across a channel resistance of the transistor in separate measuring channels when the respective transistor is conductive. Each of the measuring channels has an addition element, a low-pass filter and an analog-to-digital converter such that, in each measuring channel, signals of the respective voltage drop across the addition element and the low-pass filter are supplied to the analog-to-digital converter. The addition element of each of the measuring channels additively adds the signals of the respective measuring channel to the signals of the respective other measuring channel.

### CROSS-REFERENCE TO RELATED APPLICATIONS

This application claims the benefit of PCT Application PCT/EP2023/075216, filed Sep. 14, 2023, which claims priority to German Application 10 2022 210 524.9, filed Oct. 5, 2022. The disclosures of the above applications are incorporated herein by reference.

### TECHNICAL FIELD

The disclosure relates to a measurement structure for measuring a current from a center tap between two transistors of a half bridge through a load, and to a method for measuring a current from a center tap between two transistors of a half bridge through a load.

### BACKGROUND

In order to protect measuring channels in electronic circuits against the coupling of interference, a low-pass filter TPF is used, in most cases in the form of a first-or higher-order RC element according to FIG. 1. The low-pass filter TPF is connected in parallel with a shunt SH.

A requirement for the measurement structure shown in FIG. 1 is that the signal to be measured has a continuous characteristic. This is the case for the current I from a center tap of a half bridge composed of two transistors T1, T2 through the shunt SH, which, in this example, allows the current I to be measured by way of a voltmeter V. The voltmeter V can thus be protected against higher-frequency interference by a low-pass filter TPF. The measurement configuration in FIG. 2 does not meet this requirement.

In the example shown in FIG. 2, the voltage drop across a channel resistance of a respectively conductive transistor T1, T2 of the half bridge is measured and in turn evaluated by a voltmeter. In FIG. 2, this combination is illustrated in a simplified manner as an ammeter A. Consequently, the current I can only be measured so long as the respective transistor T1, T2 is conductive. This results in two partial current measurements, which are illustrated in FIGS. 3 and 4. In this case, FIG. 3 shows a characteristic of the current I through the upper transistor T1 over time t and FIG. 4 shows a characteristic of the current I through the lower transistor T2. Since a low-pass filter TPF only still indicates the average value of the measurement signal from about ten times the corner frequency, it cannot be used to protect the ammeter A against interference at the measurement input. As a result, the analog-to-digital converter ADC1, ADC2 customary for receiving the measurement signal is not protected, and the result is the occurrence of beats. In other words, interference signals in the higher-frequency range, such as signal jumps, are modulated into the functional range due to the violation of the Nyquist-Shannon theorem and interpreted as a measurement signal.

### SUMMARY

The disclosure provides a measurement structure and a method for measuring a current from a center tap between two transistors of a half bridge through a load.

One aspect of the disclosure provides a measurement structure for measuring a current from a center tap between two transistors of a half bridge through a load. The measurement structure is configured, for each of the two transistors, to measure a voltage across a channel resistance of the transistor in separate measuring channels when the respective transistor is conductive. Each of the measuring channels has an addition element, a low-pass filter and an analog-to-digital converter such that, in each measuring channel, signals of the respective voltage drop across the addition element and the low-pass filter are able to be supplied to the analog-to-digital converter, where the addition element of each of the measuring channels is configured to additively add the signals of the respective measuring channel to the signals of the respective other measuring channel.

In this way, the discontinuous signal characteristic in each of the measuring channels is converted into a continuous signal characteristic and filterability is therefore made possible.

In some examples, the low-pass filter is a first-or higher-order low-pass filter.

Another aspect of the disclosure provides a device having a measurement structure as described above and a half bridge. The half bridge includes two transistors, and a load fed from a center tap between the two transistors.

In some examples, the transistors are in the form of field-effect transistors, where source of the upper transistor is connected to drain of the lower transistor.

Yet another aspect of the disclosure provides a method for measuring a current from a center tap between two transistors of a half bridge through a load is proposed. For each of the two transistors, a voltage across a channel resistance of the transistor is measured in separate measuring channels when the respective transistor is conductive. In each measuring channel, signals of the respective voltage drop across an addition element and a low-pass filter are supplied to an analog-to-digital converter, where, in the addition element of each of the measuring channels, the signals of the respective measuring channel are additively added to the signals of the respective other measuring channel. In this way, the discontinuous signal characteristic in each of the measuring channels is converted into a continuous signal characteristic and filterability is therefore made possible.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a schematic view of a half bridge having a measurement structure for measuring a current from the half bridge through a load according to the prior art,

FIG. 2 shows a schematic view of a half bridge having a further measurement structure for measuring the current from the half bridge through a load according to the prior art,

FIG. 3 shows a characteristic of a current through an upper transistor of the measurement structure according to the prior art,

FIG. 4 shows a characteristic of a current through a lower transistor of the measurement structure according to the prior art,

FIG. 5 shows a schematic view of an exemplary measurement structure for measuring the current from the half bridge through a load,

FIG. 6 shows a schematic diagram of a characteristic of the current in a lower measuring channel of the exemplary measurement structure of FIG. 5,

FIG. 7 shows a further schematic view of the exemplary measurement structure of FIG. 5, and

FIG. 8 shows a schematic diagram of a characteristic of the current in an upper measuring channel of the exemplary measurement structure of FIGS. 5 and 7.

Like reference symbols in the various drawings indicate like elements.

### DETAILED DESCRIPTION

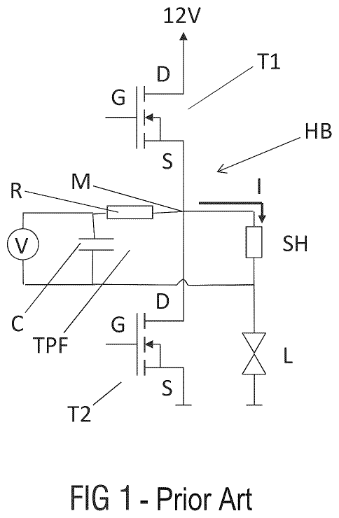

FIG. 1 is a schematic view of a half bridge HB having two transistors T1, T2, such as field-effect transistors, where source S of the upper transistor T1 is connected to drain D of the lower transistor T2. In order to measure a current I which flows from a center tap M between the two transistors T1, T2 through a load L, a measurement structure is provided which has a shunt SH between the load L and the center tap M. By measuring the voltage drop across the shunt SH by way of a voltmeter V, it is possible to determine the current I with knowledge of the resistance of the shunt SH. In order to protect measuring channels in electronic circuits against the coupling of interference, use is usually made of a low-pass filter TPF, in most cases in the form of a first- or higher-order RC element. The low-pass filter TPF illustrated by way of example includes, connected in parallel with the shunt SH, a series circuit having a resistor R and a capacitor C, the voltmeter V being connected in parallel with the capacitor.

The signal to be measured should have a continuous characteristic. This is the case for the current I from the center tap M of the half bridge HB having two transistors T1, T2 through the shunt SH, which, in this example, allows the current I to be measured by a voltmeter V. The voltmeter V can thus be protected against higher-frequency interference by the low-pass filter TPF.

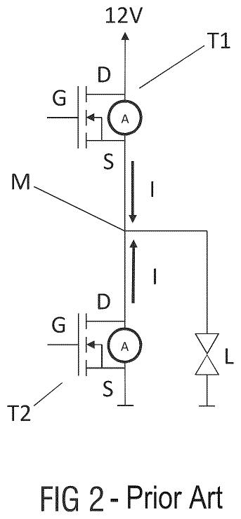

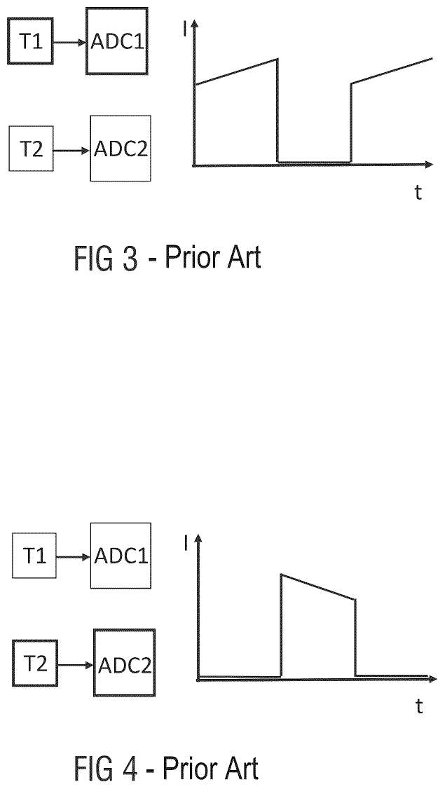

FIG. 2 is a schematic view of a half bridge HB that includes two transistors T1, T2, such as field-effect transistors, where source S of the upper transistor T1 is connected to drain D of the lower transistor T2. In order to measure a current I which flows from a center tap M between the two transistors T1, T2 through a load L, an alternative measurement structure is provided in which the voltage drop across a channel resistance of a respectively conducting transistor T1, T2 of the half bridge is measured and in turn evaluated by a voltmeter V. In FIG. 2, this combination is illustrated as an ammeter A. Consequently, the current I can only be measured so long as the respective transistor T1, T2 is conductive, for example when actuating the gates G of the transistors T1, T2 with pulse-width-modulated signals. This results in two partial current measurements, which are illustrated in FIGS. 3 and 4. In this case, FIG. 3 shows a characteristic of the current I through the upper transistor T1 over time t and FIG. 4 shows a characteristic of the current I through the lower transistor T2. Since a low-pass filter TPF only still indicates the average value of the measurement signal from about ten times the corner frequency, it cannot be used in the measurement structure according to FIG. 2 to protect against interference at the measurement input. As a result, an analog-to-digital converter ADC1, ADC2 customary for receiving the measurement signal is not protected, and the result is the occurrence of beats. In other words, interference signals in the higher-frequency range, such as signal jumps, are modulated into the functional range due to the violation of the Nyquist-Shannon theorem and interpreted as a measurement signal.

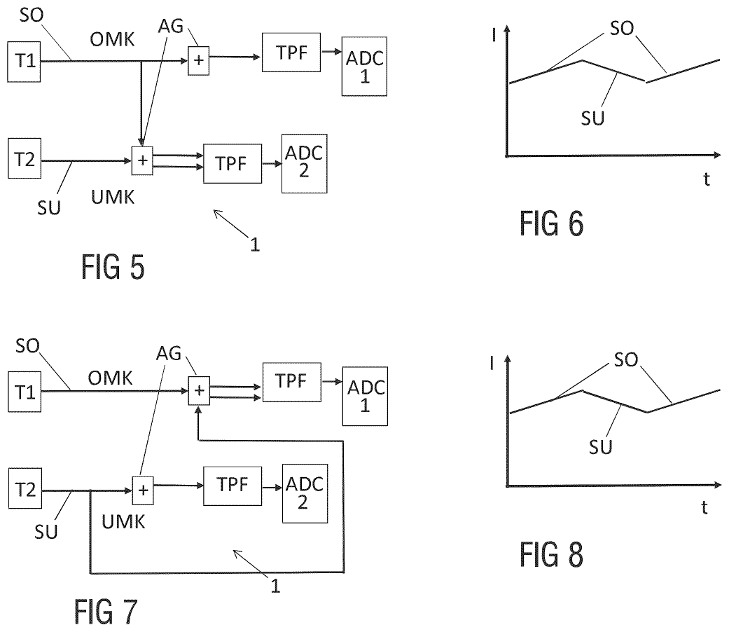

FIG. 5 is a schematic view of a measurement structure 1 having an upper

measuring channel OMK for signals SO of the voltage drop across the channel resistance of the upper transistor T1 according to FIG. 2 and having a lower measuring channel UMK for signals SU of the voltage drop across the channel resistance of the lower transistor T2 according to FIG. 2. In each of the measuring channels OMK, UMK, the signals SO, SU of the respective voltage drop across an addition element AG and a low-pass filter TPF are supplied to an analog-to-digital converter ADC1, ADC2.

In FIG. 5, the signals SO of the upper measuring channel OMK are additively added to the lower measuring channel UMK via the addition element AG. Taking into account the channel resistance, this results in a characteristic of the current I before the low-pass filter TPF as shown schematically in FIG. 6.

FIG. 7 is a schematic view of the measurement structure 1 according to FIG. 5, where the signals SU of the lower measuring channel UMK are additively added to the upper measuring channel OMK via the addition element AG. Taking into account the channel resistance, this results in a characteristic of the current I before the low-pass filter TPF as shown schematically in FIG. 8.

FIGS. 6 and 8 clearly show that signal jumps are avoided by this addition. Filtering by the low-pass filter TPF is therefore possible in the measurement structure according to FIGS. 6 and 8.

Continuing to measure only in the respectively active time window, that is to say while the respective transistor T1, T2 is conductive, further sought-after information can then be evaluated as before, for example current vertices.

A number of implementations have been described. Nevertheless, it will be understood that various modifications may be made without departing from the spirit and scope of the disclosure. Accordingly, other implementations are within the scope of the following claims.

### REFERENCE NUMERALS

1 measurement structure
A ammeter
ADC1, ADC2 analog-to-digital converter
AG addition element
C capacitor
D drain
G gate
HB half bridge
I current
L load
M center tap
OMK upper measuring channel
R resistor
S source
SH shunt
SO, SU signals
t time
T1, T2 transistor
TPF low-pass filter
UMK lower measuring channel
V voltmeter

What is claimed is:

1. A measurement structure for measuring a current from a center tap between two transistors of a half bridge through a load, the measurement structure comprising:
an addition element;
a low-pass filter; and
an analog-to-digital converter;
measuring channels, each measuring channel including the addition element, the low-pass filter, and the analog-to-digital converter;
wherein the measurement structure is configured to determine, a voltage across a channel resistance of the transistor in each of the measuring channels when the respective transistor is conductive;
wherein in each measuring channel, signals of the respective voltage drop across the addition element and the low-pass filter supplied to the analog-to-digital converter, and
wherein the addition element of each of the measuring channels additively adds the signals of the respective measuring channel to the signals of the respective other measuring channel.

2. The measurement structure of claim 1, wherein the low-pass filter is a first-or higher-order low-pass filter.

3. A device comprising:
the measurement structure of claim 1;
a half bridge comprising an upper transistor and a lower transistor; and
a load fed from a center tap between the two transistors.

4. The device of claim 3, wherein the transistors include field-effect transistors, wherein a source of the upper transistor is connected to a drain of the lower transistor.

5. A method for measuring a current from a center tap between two transistors of a half bridge through a load, the method comprising:
providing an addition element;
providing a low-pass filter;
providing an analog-to-digital converter;
providing measuring channels, each measuring channel including the addition element, the low-pass filter, and the analog-to-digital converter;
supplying, in each measuring channel, signals of the respective voltage drop across the addition element and the low-pass filter to an analog-to-digital converter, and
additively adding in the addition element of each of the measuring channels, the signals of the respective measuring channel to the signals of the respective other measuring channel; and
measuring, for each of the two transistors, a voltage across a channel resistance of the transistor in separate measuring channels when the respective transistor is conductive.
